(19) United States
(12) Patent Application Publication
(10) Pub. No.: US 2025/0334650 A1
(43) Pub. Date: Oct. 30, 2025

(54) INDUCTANCE MEASUREMENT TO DETERMINE THE HEALTH OF A TRANSFORMER

(71) Applicant: Rivian IP Holdings, LLC, Irvine, CA (US)

(72) Inventors: Chunhui Liu, Irvine, CA (US); Lixiang Wei, Irvine, CA (US); Adam John Emes, Los Angeles, CA (US); Steven Schulz, Torrance, CA (US)

(21) Appl. No.: 18/647,129

(22) Filed: Apr. 26, 2024

(51) Int. Cl. G01R 31/62

(52) U.S. Cl. CPC G01R 31/62

(57) ABSTRACT

Systems and methods for determining the health of a transformer are provided herein. A system includes a transformer, a capacitor, and control circuitry configured to discharge the capacitor across the transformer, measure a voltage across the capacitor, and determine a health of the transformer based on the measured voltage. In some embodiments, a magnetizing inductance of the transformer is determined based on the measured voltage, and the health of the transformer is determined by comparing the determined magnetizing inductance to a reference value. In some embodiments, the transformer is part of a dual active bridge (DAB) converter, and the DAB converter is controlled based on the health of the transformer.

### INTRODUCTION

The present disclosure is directed to systems and methods for determining the health of the transformer. More specifically, the present disclosure is directed to determining the health of a DAB transformer based on monitoring the voltage profile while discharging a capacitor across the transformer.

### SUMMARY

A dual active bridge (DAB) converter is a type of power electronics equipment that may use a transformer as part of a DC to DC power conversion. Before or during operation of the DAB converter, it may be useful to determine the magnetizing inductance or other electromagnetic properties of the transformer.

The health of a transformer may be determined based on comparing the magnetizing inductance of the transformer to a predetermined value. For example, control circuitry of a DAB converter may be configured to determine whether the magnetizing inductance of the transformer has, compared to an initial or previously-measured magnetizing inductance, reduced beyond a threshold difference. In some embodiments, the control circuitry may be further configured to provide an alert and/or operate the DAB converter in a modified mode (e.g., having zero power output, or power output that is reduced compared to a normal mode) in response to determining that the transformer has poor health.

In accordance with some embodiments of the present disclosure, a system includes a transformer, a capacitor, and control circuitry configured to discharge the capacitor across the transformer, measure a voltage across the capacitor, and determine a health of the transformer based on the measured voltage.

In some embodiments, the control circuitry is configured to measure the voltage across the capacitor by measuring a first voltage across the capacitor before the capacitor is discharged and measuring a second voltage across the capacitor after a predetermined amount of time, and determine the health of the transformer based on a difference between the first voltage and the second voltage. In some embodiments, the control circuitry configures a magnitude of the first voltage such that that the energy of the capacitor only discharges through the transformer winding (e.g., and does not discharge onto a different capacitor of the same bridge of the DAB converter or onto a different capacitor of the opposite bridge of the DAB converter).

In some embodiments, the predetermined amount of time is based on a time constant of a current loop including the transformer and the capacitor. In some embodiments, the current loop also includes one or more power semiconductor devices.

In some embodiments, the control circuitry is configured to determine an amount of time that the capacitor takes to fully discharge, and the control circuitry is configured to determine the health of the transformer based on the amount of time that the capacitor takes to fully discharge.

In some embodiments, the control circuitry is also configured to determine the health of the transformer based on the measured voltage by determining a magnetizing inductance of the transformer, and determining whether the magnetizing inductance is less than a reference magnetizing inductance by more than a predetermined amount.

In some embodiments, the system also includes a plurality of switches, wherein the control circuitry is also configured to close a switch of the plurality of switches, and after a predetermined amount of time has passed after closing the switch, open the switch and close a different switch of the plurality of switches, such that the capacitor stops discharging.

In some embodiments, the control circuitry is configured to close the switch by applying a pulse-width modulation (PWM) signal to the switch and wherein a duty cycle or a frequency of the PWM signal is based on a current rating of the switch.

In some embodiments, the control circuitry is also configured to, in response to determining that the transformer has poor health, generate a notification indicating the poor health of the transformer, and operate a dual active bridge converter comprising the transformer based on the poor health of the transformer.

In accordance with some embodiments of the present disclosure, a method includes discharging a capacitor across a transformer, measuring a voltage across the capacitor, and determining a health of the transformer based on the measured voltage.

In some embodiments, measuring the voltage across the capacitor includes measuring a first voltage across the capacitor before the capacitor is discharged and measuring a second voltage across the capacitor after a predetermined amount of time, and determining the health of the transformer is based on a difference between the first voltage and the second voltage. In some embodiments, the method includes configuring a magnitude of the first voltage such that that the energy of the capacitor only discharges through the transformer winding (e.g., and does not discharge onto a different capacitor of the same bridge of the DAB converter or onto a different capacitor of the opposite bridge of the DAB converter).

In some embodiments, the predetermined amount of time is based on a time constant of a current loop including the transformer and the capacitor. In some embodiments, the current loop also includes one or more power semiconductor devices.

In some embodiments, the method also includes determining an amount of time that the capacitor takes to fully discharge, wherein determining the health of the transformer based on the amount of time that the capacitor takes to fully discharge.

In some embodiments, determining the health of the transformer based on the measured voltage includes determining a magnetizing inductance of the transformer and determining whether the magnetizing inductance is less than a reference magnetizing inductance by more than a predetermined amount.

In some embodiments, the method also includes closing a switch to discharge the capacitor across the transformer, and after a predetermined amount of time has passed after closing the switch, opening the switch and closing a different switch such that the capacitor stops discharging.

In some embodiments, closing the switch includes applying a pulse-width modulation (PWM) signal to the switch and wherein a duty cycle or a frequency of the PWM signal is based on a current rating of the switch.

In some embodiments, the method also includes, in response to determining that the transformer has poor health generating a notification indicating the poor health of the transformer, and operating a dual active bridge converter comprising the transformer based on the poor health of the transformer.

In accordance with some embodiments of the present disclosure, a non-transitory computer-readable medium having non-transitory computer-readable instructions encoded thereon that, when executed by a processor, cause the processor to discharge a capacitor across a transformer, measure a voltage across the capacitor, and determine a health of the transformer based on the measured voltage.

In some embodiments, the instructions, when executed by the processor, further cause the processor to measure a first voltage across the capacitor before the capacitor is discharged and measure a second voltage across the capacitor after a predetermined amount of time, and determine the health of the transformer based on a difference between the first voltage and the second voltage.

In some embodiments, the instructions, when executed by the processor, further cause the processor to determine an amount of time that the capacitor takes to fully discharge, and determine the health of the transformer based on the amount of time that the capacitor takes to fully discharge.

In some embodiments, the instructions, when executed by the processor, further cause the processor to determine a magnetizing inductance of the transformer based on the measured voltage, and determine the health of the transformer based on determining whether the magnetizing inductance is less than a reference inductance by more than a predetermined amount.

### BRIEF DESCRIPTION OF THE DRAWINGS

The above and other objects and advantages of the disclosure will be apparent upon consideration of the following detailed description, taken in conjunction with the accompanying drawings, in which like reference characters refer to like parts throughout, and in which:

FIG. 1 shows an illustrative block diagram of an electric vehicle charging system including power electronics equipment for providing power to a load and/or an energy storage system, in accordance with some embodiments of the present disclosure;

FIG. 2 is an illustrative block diagram showing additional details of some components of power electronics equipment, in accordance with some embodiments of the present disclosure;

FIG. 3 is an illustrative circuit schematic of a dual active bridge (DAB) converter in a first state, in accordance with some embodiments of the present disclosure;

FIG. 4 is an illustrative depiction of a dual active bridge (DAB) converter in a second state, in accordance with some embodiments of the present disclosure;

FIG. 5 is an illustrative depiction of control signals and an output voltage during a first scheme for determining the health of transformer of a DAB converter, in accordance with some embodiments of the present disclosure;

FIG. 6 is an illustrative depiction of control signals and an output voltage during a second scheme for determining the health of transformer of a DAB converter, in accordance with some embodiments of the present disclosure;

FIG. 7 is an illustrative flowchart of a method for determining the health of a transformer, in accordance with some embodiments of the present disclosure; and

FIG. 8 shows illustrative relationships between measured properties of a discharging capacitor and the magnetizing inductance of a transformer, in accordance with some embodiments of the present disclosure.

### DETAILED DESCRIPTION

Power electronics equipment may include a transformer as part of a system that provides power to a load. For example, a dual active bridge (DAB) converter is a type of power electronics equipment that uses a transformer to transfer power from a grid, generator, or other source to a load (e.g., a battery in an electric vehicle).

In some embodiments, a specific value or range of the magnetizing inductance (or other electromagnetic property) of the transformer may relate to the reliable and/or efficient operation of the DAB converter. For example, over a lifetime of operation in the field, the magnetizing inductance of a transformer of a DAB converter may reduce compared to an initial magnetizing inductance of the transformer (e.g., as occurs before, during, or shortly after its commissioning). This reduction in magnetizing inductance, or other related performance losses associated with the transformer, may be consequences of manufacturing imprecision, mechanical, electrical, and/or thermal stress induced during handling and/or operation, or any combination thereof. In particular, certain transformers with otherwise desirable performance features (e.g., transformers with nanocrystalline cores or any other materials with stacked laminations) may be susceptible to reductions in their magnetizing inductance while operating out in the field.

Consequences of a change in the properties of a transformer can include a short-circuit of the transformer core (e.g., due to a localized short occurring between adjacent transformer core laminations), a drop in the electromagnetic permeability, a reduction in the impedance, an increase in the core losses, or any combination thereof. These property changes may reduce the efficiency and/or performance capabilities of electronic systems using the transformer. In addition, these property changes can be detected by measuring the inductance or the core loss across the transformer and comparing the measured values to reference values (e.g., initial values, values from previous measurements, or predetermined threshold values). A health of the transformer can therefore be determined based on a difference between the measured value and the reference value. Based on monitoring the health of the transformer, reliable and efficient operation of a DAB converter including the transformer may be achieved.

In accordance with embodiments of the present disclosure, systems and methods (that, e.g., may be performed dynamically, with or without automation) are provided for determining the health of a transformer. In some embodiments, the transformer links primary and secondary side bridges of a DAB converter, and the health of the transformer is determined by control circuitry of the DAB converter. The control circuitry is configured to discharge one or more capacitor (e.g., of the secondary side bridge) across the transformer, measure a voltage across the capacitor during the discharge process, and determine a health of the transformer based on the measured voltage. It is noted that in some embodiments of the present disclosure, multiple capacitors are configured in parallel, and this configuration of parallel capacitors may be treated or regarded as a single capacitor (e.g., with a lumped capacitance equal to the sum of the respective capacitors that are configured in parallel).

In some embodiments, the control circuitry is configured to implement one or more specific control schemes to discharge and measure the voltage across the capacitor. In a first control scheme, the voltage is measured while discharging the capacitor for a predetermined amount of time (e.g., based on a time constant of the current loop including the transformer and the capacitor), and the health of the transformer is determined based on the difference between the voltage levels measured before and after the predetermined amount of time. In a second control scheme, the voltage is measured while fully discharging the capacitor (e.g., to a substantially non-zero or otherwise substantially constant voltage), and the health of the transformer is determined based on the amount of time the capacitor took to fully discharge.

In some embodiments, based on the measured voltage (e.g., based on the voltage level difference or the time the capacitor required to fully discharge), the control circuitry is configured to determine the magnetizing inductance of the transformer. The control circuitry is further configured to determine a health of the transformer based on determining whether the magnetizing inductance deviates from a reference magnetizing inductance by more than a predetermined amount.

In some embodiments, based on determining that health of the transformer is poor (e.g., based on determining that the magnetizing inductance is lower than the reference magnetizing inductance by more than the predetermined amount), the control circuitry is configured to generate a notification indicating the poor health of the transformer. The control circuitry may be further configured to operate the DAB converter in one or more possible modified modes based on the health of the transformer. For example, one modified operating mode may permit only a limited amount of power from flowing through the transformer (e.g., in response to the inductance deviation being above a first threshold); another modified operating mode may prevent any power from flowing through the transformer (e.g., in response to the inductance deviation being above a second threshold, greater than the first).

Accordingly, as described above and as further described in detail below, methods and corresponding systems and computer-readable media are provided for using control circuitry of a DAB converter to determine the health of the transformer of the DAB converter.

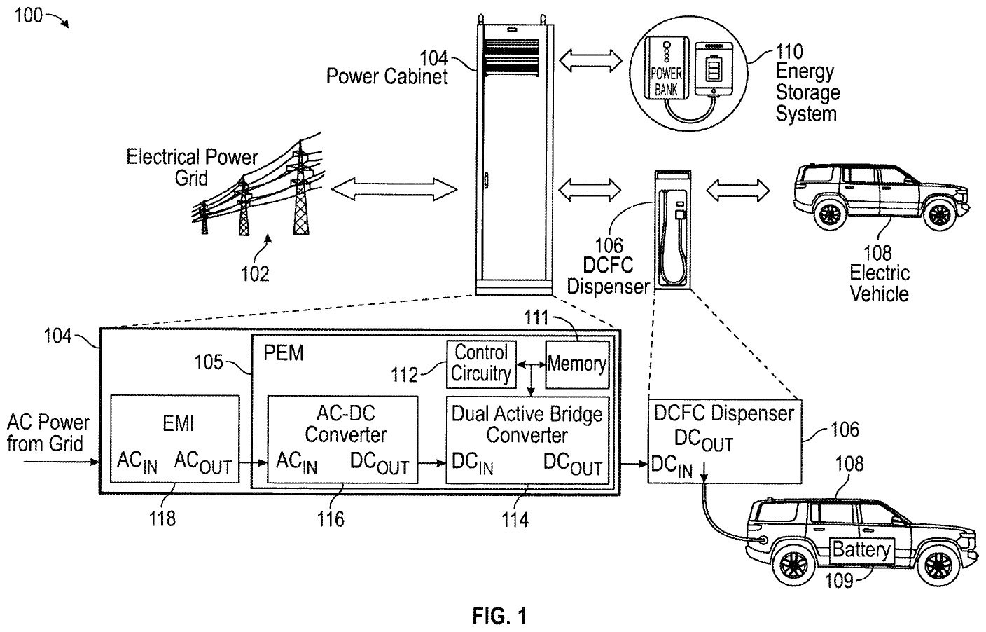

FIG. 1 depicts an illustrative block diagram 100 of an electric vehicle charging system including a DAB converter for providing power to a load and/or an ESS, in accordance with some embodiments of the present disclosure. Power is input to the system by electrical power grid 102, which is coupled to power cabinet 104. Power cabinet 104 is coupled to direct current fast charge (DCFC) dispenser 106. Through a direct connection or through dispenser 106, power cabinet 104 ultimately delivers power to at least one of electric vehicle 108 (specifically battery 109 therein) and/or energy storage system (ESS) 110. Power cabinet 104 includes one or more power electronics module (PEM) 105, each of which includes DAB converter 114 as well as memory 111 and control circuitry 112, where memory 111 may include instructions for operating control circuitry 112 to control DAB converter 114 according to the operations described above and as further described below. In some embodiments, DAB converter 114 is electrically isolated from other components of block diagram 100 and is configured for bidirectional flow (e.g., DAB converter 114 can either send power to or receive power from DCFC dispenser 106 or ESS 110). Embodiments of the present disclosure may serve either direction of power flow through DAB converter 114. Additionally included in PEM 105 is AC to DC converter 116, which may convert incoming AC power from the electric grid to a first DC power that can then be converted into a second DC power (e.g., by DAB converter 114) for powering connected loads. In some embodiments, AC to DC converter 116 may convert incoming DC power (e.g., from electric vehicle 108 or ESS 110, through DAB converter 114) to AC power that may be supplied to the electric grid (e.g., to provide grid support) or AC loads (e.g., to provide backup power, grid islanding, supplemental power, any other suitable source of AC power, or any combination thereof).

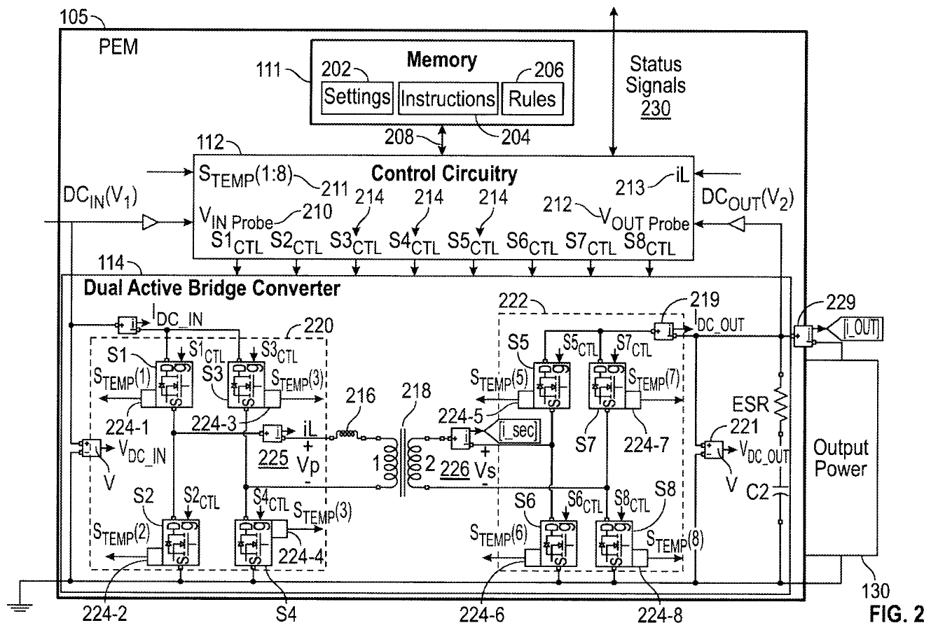

FIG. 2 is an illustrative block diagram showing additional details of some components of power electronics equipment, in accordance with some embodiments of the present disclosure. Memory 111 may be an electronic storage device. As referred to herein, the phrase “electronic storage device” or “storage device” will be understood to mean any device for storing electronic data, computer software, or firmware, such as random-access memory, read-only memory, solid state devices, or any other suitable fixed or removable storage devices, and/or any combination thereof. Memory 111 may be used to store various types of instructions, rules, and/or other types of data. For example, memory 111 may include instructions for how to discharge a capacitor across the transformer and measure the voltage of the capacitor while it is discharging. Furthermore, memory 111 may include rules (e.g., reference values for the magnetizing inductance, the electromagnetic permeability, the impedance, and/or the core losses of a transformer) for determining the health of a transformer (e.g., based on assigning one or more thresholds or one or more predetermined magnitudes associated with a deviation between a reference value of a transformer property and a measured value of a transformer property). In some embodiments, control circuitry 112 executes instructions for an application stored in memory 111 (e.g., to implement one or more switching schemes to determine the health of the transformer of DAB converter 114). Specifically, control circuitry 112 may be instructed by the application to perform the functions discussed herein, including sending control signals to toggle individual switches and/or legs of switches. In some embodiments, any action performed by control circuitry 112 may be based on instructions received from the application. In some embodiments, the application may be implemented as software or a set of executable instructions that may be stored in memory 111 and executed by control circuitry 112.

Memory 111 may store settings 202, instructions 204, and rules 206. Example types of settings 202 may include PEM output settings, DAB control settings (e.g., DAB switch toggling settings), DAB switching schemes (e.g., for measuring the health of the transformer), duty cycle settings (e.g., for maintaining switches of the DAB converter below a threshold temperature limit), delay settings (e.g., as may be associated with states of the DAB converter), other types of settings, or any combination thereof. Example types of rules 206 include mappings for applying DAB control settings based on PEM output settings, computational constants (e.g., any one or more electromagnetic properties of the inductors, transformers, switches, transistors, capacitors, or other electronics of DAB converter 114), overvoltage conditions, overcurrent conditions, negative current conditions, switching sequences, DAB models, DAB controls, snubber capacitances, other types of information or data, or any combination thereof. In some embodiments, instructions 204 are executed by control circuitry 112 to implement steps of various methods described herein (e.g., based on applicable settings 202 and/or rules 206).

DAB converter 114 includes transformer 218 (which has a magnetizing inductance that may be determined by the control circuitry) including a primary bridge winding and a secondary bridge winding, primary side bridge 220, and secondary side bridge 222. Primary side bridge 220 is coupled to a primary side of transformer 218 through series inductor 216. Secondary side bridge 222 is coupled to a secondary side of transformer 218. As used herein, the “primary side” or “primary bridge” of a DAB converter (e.g., DAB converter 114) may refer to the portion of a DAB converter appearing to the left of a transformer (e.g., transformer 218), and the “secondary side” or “secondary bridge” of DAB converter 114 may refer to the portion of a DAB converter appearing to the right of a transformer. As used herein, Vp and Vs refer to the voltage on the primary side of transformer 218 and the voltage on the secondary side of transformer 218, respectively. DAB converter 114 also includes primary side switches S1, S2, S3, and S4 located on the primary side of DAB converter 114 and secondary side switches S5, S6, S7, and S8 located on the secondary side of DAB converter 114. As used herein, a “leg” of a DAB converter bridge refers to a pair of switches that are coupled in series (e.g., switches S1 and S2, S3 and S4, S5 and S6, or S7 and S8). Switches S1, S2, S3, S4, S5, S6, S7, and S8 may be any suitable type of electronic switch, such as a field effect transistor (FET)-based switch, that can be enabled (e.g., switched on/closed, during which current is permitted to be conducted between its source and drain terminal) or disabled (e.g., switched off/open, during which current is effectively prevented from being conducted between its source and drain terminal) by changing a logic level of the control signal provided to its gate terminal, for example from a logic-high to a logic-low. In some embodiments, legs of DAB converter 114 may be toggled (e.g., periodically opened and closed) in response to control signals from control circuitry 112, where such signals may correspond to a desired power output of PEM 105 and may include particular temporal delays to configure how a capacitor discharges across the transformer, control power output, and achieve other desirable control effects, or any combination thereof. In some embodiments, switches S1-S8 may be wide bandgap (WBG) based power semiconductors, such gallium nitride (GaN) or silicon carbide (SiC) based semiconductors. In some embodiments, switches S1-S8 may include other types of metal-oxide-semiconductor field-effect transistors (MOSFETs). As shown, each of the switches S1-S8 includes an anti-parallel diode.

In some embodiments, temperature sensors 224-1, 224-2, 224-3, 224-4, 224-5, 224-6, 224-7, and 224-8 (collectively referred to as temperature sensors 224), are coupled to, and configured to measure the temperatures of, switches S1, S2, S3, S4, S5, S6, S7, and S8, respectively. Temperature sensors 224-1, 224-2, 224-3, 224-4, 224-5, 224-6, 224-7, and 224-8, output to control circuitry 112 signals (S_{TEMP}(1) through S_{TEMP}(8), collectively, S_{TEMP}(1:8)) indicating sensed temperatures of switches S1 through S8, respectively. In some embodiments, data from one or more temperature sensors 224-1, 224-2, 224-3, 224-4, 224-5, 224-6, 224-7, and 224-8 may be indicative of voltage levels and/or temperature changes occurring across switches S1-S8. Complete signal paths from output ports S_{TEMP}(1) through S_{TEMP}(8) of temperature sensors 224-1, 224-2, 224-3, 224-4, 224-5, 224-6, 224-7, and 224-8 to temperature input port 211 (S_{TEMP}(1:8)) of control circuitry 112 are omitted from FIG. 2 for clarity. Nonetheless, output ports S_{TEMP}(1) through S_{TEMP}(8) of temperature sensors 224-1, 224-2, 224-3, 224-4, 224-5, 224-6, 224-7, and 224-8 are indeed coupled to temperature input port 211 (S_{TEMP}(1:8)) of control circuitry 112 through a signal bus or other suitable respective signal paths. In some embodiments, one or more of temperature sensors 224 may be omitted. For example, in some embodiments, only a single temperature sensor may be provided for each leg or for each side of DAB converter 114.

In some embodiments, current sensor 229 is configured to sense output current (i_OUT) of PEM 105 and output to control circuitry 112 a signal indicating the output current as is delivered to output power 130. A signal from current sensor 229 may be used to determine a switching scheme of DAB converter 114 (e.g., how to toggle the legs therein). For example, current sensor 229 may indicate an output power 130 of PEM 105, where the output power may be associated with a particular switching scheme of DAB converter 114. Similarly, current sensor 219 is configured to sense an output current (I_{DC_OUT}). Current sensor 219 may be configured the same as current sensor 229, including to be used by control circuitry 112 to determine a switching scheme of DAB converter 114.

In some embodiments, voltage sensor 221 may be coupled in parallel to current sensor 219 to measure an output voltage (V_{DC_OUT}) of PEM 105, and a signal from voltage sensor 221 may also be used to determine a health of transformer 218 of DAB converter 114. For example, the output voltage (V_{DC_OUT}) may correspond to the voltage across the capacitor that discharges across the transformer to determine one or more properties (e.g., including the magnetizing inductance) of the transformer 218.

In some embodiments, current sensor 226 is configured to sense the current across the secondary side of transformer 218 and to output to control circuitry 112 a signal indicating the secondary side transformer current. In some embodiments, a signal from current sensor 226 (with or without the signal from current sensor 219) may be used to determine a switching scheme (e.g., for measuring a property of the transformer 218) of DAB converter 114. In some embodiments, a voltage sensor may be coupled in parallel to current sensor 226 or in another suitable location to measure a transformer voltage. In some embodiments, with or without the signal from voltage sensor 221, such a voltage sensor may be used to measure a voltage at a node of the DAB converter 114 and correspondingly determine a health of the transformer 218.

In some embodiments, current sensor 225 is configured to sense the current across the primary side of transformer 218 and output to control circuitry 112 a signal indicating the primary current. In some embodiments, a signal from current sensor 225 (with or without the signal from current sensor 219) may be used to determine a switching scheme (e.g., for measuring a property of the transformer 218) of DAB converter 114. In some embodiments, a voltage sensor may be coupled in parallel to current sensor 225 or in another suitable location to measure a transformer voltage (e.g., for determining the health of the transformer 218). In some embodiments, voltage sensor 221 or any other voltage sensor may be used to determine a switching scheme of DAB converter 114.

Control circuitry 112 includes memory interface port 208, first input port 210 (V_{IN Probe}), temperature input port 211, second input port 212 (V_{OUT Probe}), current input port 213, and multiple output ports 214. Control circuitry 112 is configured to transmit and receive instructions, settings, rules, and/or other types of data to and from memory 111 via memory interface port 208. For example, control circuitry 112 may be configured to implement particular switch toggling schemes (e.g., for measuring signals indicative of a property of the transformer 218) based on instructions from memory 111. Control circuitry 112 is configured to sense a temperature of one or more of switches S1-S8. Control circuitry 112 is configured to sense a secondary-side output voltage (e.g., V_{OUT Probe}) via input port 212. In some embodiments, the voltage from voltage input port 212 is measured to determine a health of transformer 218. In some embodiments, the instructions 208 provided to control circuitry 112 are based on a desired scheme for determining the health of transformer 218, one or more voltage signals recorded in DAB converter 114, one or more temperature sensors of DAB converter 114, system status indicators, any other suitable information, or any combination thereof

Output ports 214 include primary switching control ports S1_{CTL}, S2_{CTL}, S3_{CTL}, and S4_{CTL}, by which control circuitry 112 provides respective switch control signals to respective switching control ports S1_{CTL}, S2_{CTL}, S3_{CTL}, and S4_{CTL} of primary side switches S1, S2, S3, and S4. Output ports 214 also include secondary switching control ports S5_{CTL}, S6_{CTL}, S7_{CTL}, and S8_{CTL}, by which control circuitry 112 provides respective switch control signals to respective switching control ports S5_{CTL}, S6_{CTL}, S7_{CTL}, and S8_{CTL} of secondary side switches S5, S6, S7, and S8, respectively. Complete signal paths from switching control ports S1_{CTL}, S2_{CTL}, S3_{CTL}, S4_{CTL}, S5_{CTL}, S6_{CTL}, S7_{CTL}, and S8_{CTL} of control circuitry 112 to S1_{CTL}, S2_{CTL}, S3_{CTL}, S4_{CTL}, S5_{CTL}, S6_{CTL}, S7_{CTL}, and S8_{CTL} of DAB 114 are omitted from FIG. 2 for clarity. Nonetheless, switching control ports S1_{CTL}, S2_{CTL}, S3_{CTL}, S4_{CTL}, S5_{CTL}, S6_{CTL}, S7_{CTL}, and S8_{CTL} of control circuitry 112 are indeed coupled to S1_{CTL}, S2_{CTL}, S3_{CTL}, S4_{CTL}, S5_{CTL}, S6_{CTL}, S7_{CTL}, and S8_{CTL} of DAB 114 via respective signal paths. In some embodiments, control circuitry 112 is configured to cause switch toggling based on sending control signals (e.g., switch control signals S1_{CTL}, S2_{CTL}, S3_{CTL}, S4_{CTL} of primary side bridge 220, and/or switch control signals S5_{CTL}, S6_{CTL}, S7_{CTL}, and S8_{CTL} of secondary side bridge 222) that are provided according to a switching sequence to cause a capacitor (e.g., of secondary side bridge 222) to discharge across transformer 218. In some embodiments, control circuitry 112 is configured to cause switch toggling based on sending control signals (e.g., including to maintain switches in the open state) that are provided according to one or more modified power operation modes (e.g., where the modified mode of DAB converter operation corresponds to the health of transformer 218).

The output of DAB converter 114 is coupled to a load that is configured to receive output power 130. For example, either of electric vehicle 108 or ESS 110 may be charged using output power 130. In response to dynamic power requirements of output power 130, control circuitry 112 may adjust switching schemes of DAB converter 114 to deliver particular levels of dynamic power. For example, DAB converter 114 may provide more power (e.g., faster charging) when the state-of-charge of electric vehicle 108 or ESS 110 is low (e.g., less than 5%, 10%, 20%, or any other suitable low state-of-charge) and DAB may provide less power (e.g., slower charging) when the state-of-charge of electric vehicle 108 or ESS 110 is high (e.g., greater than 80%, 90%, 95%, or any other suitable high state-of-charge). For another example, DAB converter 114 may provide an amount of power (which may be zero power) that is determined to be suitable based on a determination of the health of transformer 218.

In some embodiments, types of switches and/or switch configurations that differ from those shown in FIG. 2 may be utilized (e.g., switches with source and drain terminals located in positions that are the opposite of those shown in FIG. 2, active-high switches that are enabled with a logic-high gate voltage, active-low switches that are enabled with a logic-low gate voltage, or the like). The particular switches and configurations and logic levels shown and described herein are provided as illustrative examples. The principles herein apply similarly to other types of switches and/or switch configurations. The switches relating to the examples described herein are active-high switches that are closed (e.g., turned on) with a logic-high gate voltage and are open (e.g., turned off) with a logic-low gate voltage.

In some embodiments, control circuitry is configured to send status signals 230 (e.g., indicating the health of the transformer 218). For example, control circuitry may send a command to communication circuitry (e.g., of PEM 105) and one or more recipients of the status signal 230, with the command indicating a health of the transformer 218.

Although a PEM 105 is illustrated and described, it should be understood that DAB converter 114 may be used for any power system that includes handling of direct current (DC) as an input, output, or intermediate power, such as to charge electric vehicle 108 or ESS 110.

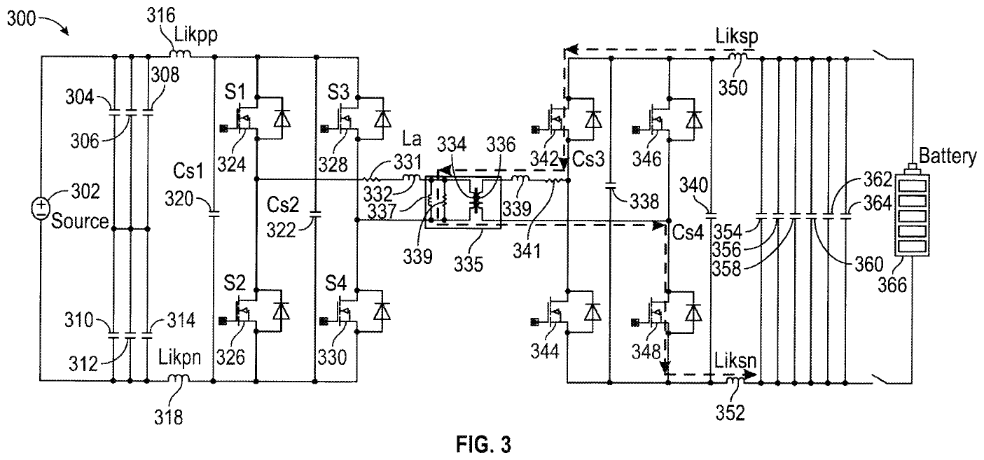

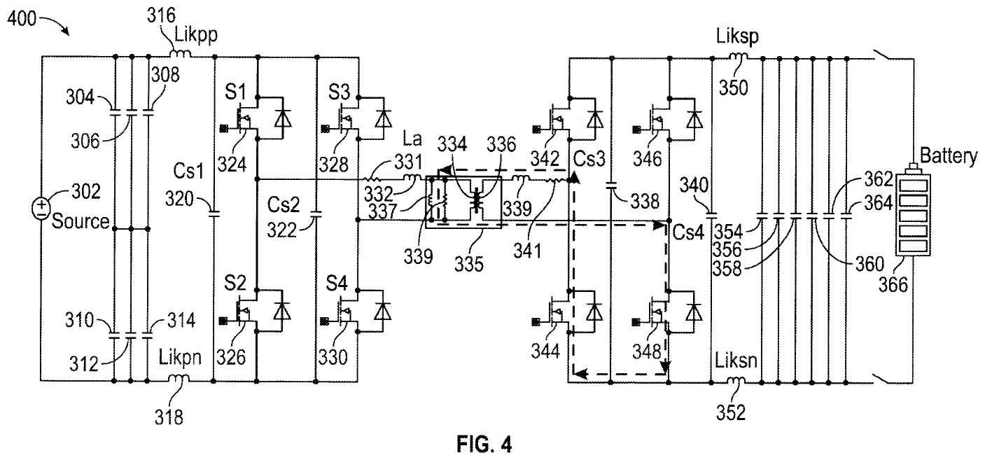

FIG. 3 is an illustrative configuration 300 of a dual active bridge (DAB) converter, in accordance with some embodiments of the present disclosure. In some embodiments, configuration 300 corresponds to one possible way of operating DAB converter 114 (e.g., to determine the health of a transformer of DAB converter 114). In some embodiments, elements 324, 326, 328, 330, 332, 342, 344, 346, 348, and 366, may correspond to elements S1, S2, S3, S4, 216, S5, S6, S7, S8, and 130, respectively. In some embodiments, windings 334 and 336 may correspond to the primary bridge winding of transformer 218 and the secondary bridge winding of transformer 218, respectively. In some embodiments, source 302 may correspond to DC_{IN} power provided to DAB 114. In some embodiments, battery 366 may correspond to battery 109, ESS 110, or a combination thereof. In some embodiments, as shown in FIGS. 3 and 4, when operating the DAB converter to determine the health of the transformer, the DAB converter may be disconnected from the battery 366 (or disconnected from any other load served by the DAB converter).

A DAB converter (e.g., DAB converter 114) may transfer DC power from source 302 to battery 366. The DAB converter of FIG. 3-4 (e.g., DAB converter 114) includes transformer 335 with primary bridge winding 334 and secondary bridge winding 336. On the primary bridge side, the DAB converter includes bulk DC capacitors 304, 306, 308, 310, 312, and 314, snubber capacitors 320 and 322, switches 324 and 326 (e.g., first leg switches), switches 328 and 330 (e.g., second leg switches), and inductor 332. On the secondary bridge side, the DAB converter includes bulk DC capacitors 354, 356, 358, 360, 362, and 364, snubber capacitors 338 and 340, switches 342 and 344 (e.g., third leg switches), and switches 346 and 348 (e.g., fourth leg switches). In some embodiments, any one or more of these secondary bridge capacitors may be used for discharging a capacitor across the transformer 335 (which may correspond to transformer 218) and may be monitored for measuring the voltage across the capacitor while it is discharging. The bulk DC capacitors may improve an impedance matching between source 302 and primary bridge side components, or between battery 366 and secondary bridge side components. The snubber capacitors may absorb resonant DC power (e.g., ripple currents generated in response to switch toggling). The switches may be toggled to control power flows across transformer 335. Inductor 332 may be a physical inductor, or it may be shown to represent a leakage inductance of primary bridge winding 334. Similarly, resistor 331 is shown to represent a resistance of the circuit path coupled to primary bridge winding 334. Likewise, inductor 339 and resistor 341 are shown to respectively represent a leakage inductance of secondary bridge winding 336 and a resistance of the circuit path coupled to secondary bridge winding 336. In addition, inductances 316, 318, 350, and 352 are shown as discrete elements; however, it will be understood that these inductances may not represent winding-based inductors, but rather may represent non-zero leakage inductances present in the circuit. For example, each of the respective leakage inductances may be attributed to non-zero inductances of wires, capacitors, transformers, other discrete electronic devices, lumped circuit components, or any combination thereof.

Moreover, magnetizing inductance 337 and magnetizing resistance 339 respectively represent the inductance and resistance properties of transformer 335. These symbols do not correspond to a physical winding or a discrete resistor. This magnetizing inductance 337 may be measured to determine a health of the transformer 335. This magnetizing resistance 339 may additionally be estimated or measured (e.g., based on an amount of power loss that occurs through the core of the transformer 335) toward determining the health of the transformer 335. In some embodiments, the magnetizing inductance 337 may be determined remotely and/or automatically, including using a procedure that does not require any opening or manual probing of the DAB converter 114.

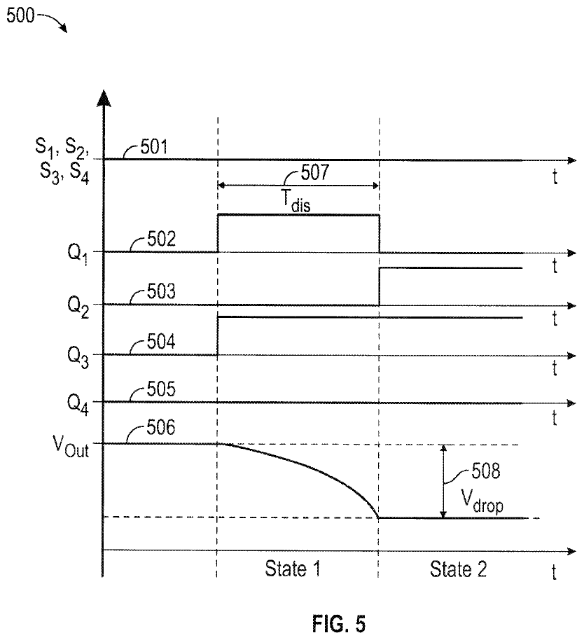

FIG. 3 shows a first configuration 300 of a DAB converter circuit for determining a health of the transformer of the DAB converter. Power flows associated with this configuration 300 are shown by the arrows overlaid on the circuit schematic. In this configuration 300, the DAB converter 114 may be referred to as being in a first state. It is noted that at the time preceding this configuration 300 (e.g., before closing switch 342), there is a nonzero output voltage across the capacitors 354, 356, 358, 360, 362, and 364. The inclusion of those six capacitors is merely illustrative; any number of one or more capacitors may be wired in parallel with battery 366 and discharged as shown in configuration 300 to determining the health of the transformer 335. As shown in FIG. 5, in which the time preceding “State 1” may correspond to the time preceding configuration 300, the output voltage, Vₒᵤₜ 506, is nonzero.

In configuration 300, switches 342 and 348 are caused to be closed (e.g., based on receiving signals from control circuitry of the DAB converter). As shown in FIG. 5, switch signal Q₁ 502 (e.g., corresponding to switch 342) and switch signal Q₃ 504 (e.g., corresponding to switch 348) are toggled from logic-low to logic-high, causing those switches to close. Due to the closing of these switches and the nonzero Vₒᵤₜ 506, power flows from a top plate of one or more of the capacitors 354, 356, 358, 360, 362, and 364, through switch 342, through the transformer 335, through switch 348, and onto a bottom plate of one or more of the capacitors 354, 356, 358, 360, 362, and 364. Thus, the control circuitry causes a capacitor to discharge across the transformer. As shown in FIG. 5, Vₒᵤₜ 506 reduces during this discharge process and is monitored (e.g., by voltage sensor 221) before, during, and after this discharge process.

In configuration 300, the primary bridge switches 324, 326, 328, and 330 are all caused to be open (e.g., as shown in FIG. 5 by primary bridge switch signal 501). Thus, the power that is discharged from one or more of the capacitors 354, 356, 358, 360, 362, and 364 mainly flows through the magnetizing inductance 337 and the output capacitance (e.g., the sum of the respective capacitances of capacitors 354, 356, 358, 360, 362, and 364).

In configuration 300, a rate at which Vₒᵤₜ 506 reduces is based on the time constant of the current loop indicated by the arrowed lines. This time constant mainly depends on the magnetizing inductance 337 and the output capacitance (e.g., the sum of the respective capacitances of capacitors 354, 356, 358, 360, 362, and 364). In some embodiments, the control circuitry is configured to determine a discharge time T_{dis} 507 based on the time constant of the discharge current loop. For example, the discharge time may be set to half of the time constant, a quarter of the time constant, an eighth of the time constant, or any other suitable fraction of the time constant, such that Vₒᵤₜ 506 decreases for the duration of the time during which the DAB circuit is in state 1 (e.g., configuration 300).

FIG. 4 shows a second configuration 400 of a DAB converter circuit for determining a health of the transformer of the DAB converter. Power flows associated with this configuration 400 are shown by the arrows overlaid on the circuit schematic. In this configuration 400, the DAB converter 114 may be referred to as being in a second state. As shown in FIG. 5, the second state may follow the first state as part of a method for determining the health of transformer 335. In particular, the control circuitry may cause the second state (e.g., configuration 400) to occur after the initialization of the first state (e.g., configuration 300) plus the discharge time T_{dis} 507, as shown in FIG. 5.

In configuration 400, switch 342 is caused to be opened and switch 344 is caused to be closed (e.g., based on receiving signals from control circuitry of the DAB converter), while switch 348 maintains its state of being closed. As shown in FIG. 5, control circuitry toggles switch signal Q₁ 502 from logic-high to logic-low, and control circuitry toggles switch signal Q₂ 503 (e.g., corresponding to switch 344) from logic-low to logic-high at the transition between states 1 and 2 (e.g., between configurations 300 and 400). Switch signal Q₃ 504 remains at a logic-high position and switch signal Q₄ (e.g., corresponding to switch 346) remains at a logic-low position.

Due to the opening and closing of these switches, the prior current flow as shown in configuration 300, and the tendency of inductors (e.g., of transformer 335) to resist changes in current, current flows through configuration 400 as indicated by the arrowed lines. The control circuitry induces current flow in configuration 400 that stops one or more of capacitors 354, 356, 358, 360, 362, and 364 from discharging, such that Vₒᵤₜ 506 remains substantially constant (as shown in FIG. 5) in the second state of the DAB converter. It is noted that the current flow dampens as the stored energy in one or more inductors (e.g., of transformer 335) discharges through the loop. In some embodiments, to accelerate a rate of dissipating the energy stored in the transformer 335 (e.g., for thermal management or to more quickly execute a method for determining the health of the transformer 335), switches 326 and 330 may be closed (e.g., the control circuitry may send these switches a logic-high signal) to provide additional current discharge paths.

In configuration 400, Vₒᵤₜ 506 remains substantially constant, and the control circuitry (e.g., control circuitry 112) may be configured to determine the magnitude of a reduction in Vₒᵤₜ 506 that occurred during the first state of the DAB converter (e.g., configuration 300). In other words, the control circuitry may be configured to calculate V_{drop} 508 as the difference between a first voltage (e.g., recorded prior to initializing the configuration 300) and a second voltage (e.g., after settling of the configuration 400), as shown in FIG. 5. Based on data stored in settings 202, instructions 204, rules 206, or any combination thereof, the control circuitry may be configured to calculate the magnetizing inductance 337 as a function of the magnitude of V_{drop} 508.

For example, the data used to calculate the magnetizing inductance 337 may include any one or more of the magnetizing resistance (e.g., which may be known or which may be measured based on a power drop occurring across the core of the transformer 335), the primary bridge winding 334 leakage inductance (e.g., as shown by inductance 332), the secondary bridge winding 336 leakage inductance (e.g., as shown by inductance 339), the primary bridge winding 334 series resistance (e.g., as shown by resistance 331), the secondary bridge winding 336 series resistance (e.g., as shown by resistance 341), and the channel resistances of any one or more switches 324, 344, 346, or 348.

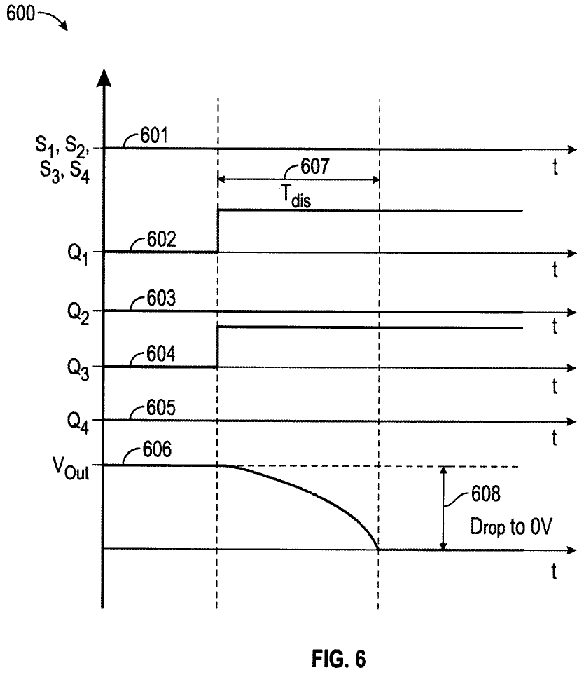

In some embodiments, it may be empirically determined that inaccuracies (e.g., where the value used in a calculation may be half or double the true value) in any of the aforementioned data that is used to calculate the magnetizing inductance 337 may cause negligible changes (e.g., of less than 1% or less than 5-10%) to the calculated magnetizing inductance. Therefore, in some embodiments, the aforementioned data used to calculate the magnetizing inductance 337 may be estimated (e.g., according to expected or average characteristics of the physical components of the DAB converter 114 and/or according to predictions made by physical models). Based on these properties, the method described herein is considered to be a robust approach to determining the health of the transformer.

Where FIG. 5 shows illustrative control signals and an illustrative output voltage curve recorded during a first scheme for determining the health of transformer of a DAB converter, FIG. 6 shows illustrative control signals and an illustrative output voltage curve recorded during a second scheme for determining the health of transformer of a DAB converter. In this second scheme, control circuitry causes the DAB converter to remain in configuration 300 (e.g., the first state) until the capacitor fully discharges. As shown in FIG. 6, the corresponding T_{dis} 607 reflects the amount of time that occurs until Vₒᵤₜ 606 reduces to zero, and the corresponding V_{drop} 608 is roughly equal to the initial magnitude of Vₒᵤₜ 606 (because this voltage has reduced to zero). It is noted that as used herein, zero voltage refers to any voltage that is suitably close to zero. For example, a particular threshold (e.g., 5 V, 1 V, 0.1 V, or any other suitable threshold) that is suitably close to 0 V may be established, and control circuitry may determine that a signal is at zero voltage when the signal magnitude is less than the particular threshold. For another example, a particular percentage of an initial voltage (e.g., 5%, 1%, 0.1%, or any other suitable percentage) may be established, and control circuitry may determine that a signal is at zero voltage when the signal magnitude is less than the particular percentage of the initial voltage.

As mentioned above, the discharge time T_{dis} 607 depends on the magnetizing inductance 337 of the transformer 335, such that this magnetizing inductance may be calculated based on monitoring the length of the discharge time T_{dis} 607 (e.g., the amount of time that occurs between beginning to discharge the one or more capacitors 354, 356, 358, 360, 362, and 364 and recording a zero (or substantially zero) voltage across these one or more capacitors). Similar to the first scheme for measuring the health of a transformer of a DAB converter, the control circuitry may be configured such that, in this second scheme for measuring the health of a transformer of a DAB converter, the magnetizing inductance 337 may be calculated based on the discharge time T_{dis} 607 and any (or all) of the aforementioned data used to calculate the magnetizing inductance 337. In some embodiments, this second scheme is also empirically shown to be robust, as described above.

In some embodiments, discharging the capacitor may thermally stress switches of the DAB converter (e.g., secondary bridge switches 342, 344, and/or 348). For example, a high rate of decrease in Vₒᵤₜ 506 or Vₒᵤₜ 606 may result in large current amplitudes flowing through the switches, which may risk damaging these switches. To avoid damaging these switches, a pulse-width modulation (PWM) method may be used (e.g., in place of any one or more of the static logic-high switches shown in signals 502, 503, 504, 602, or 604). In such a method, the control circuitry may apply a particular duty cycle and/or frequency of the PWM signal such that the current flows through the switches are reduced to magnitudes that avoid damaging the switches.

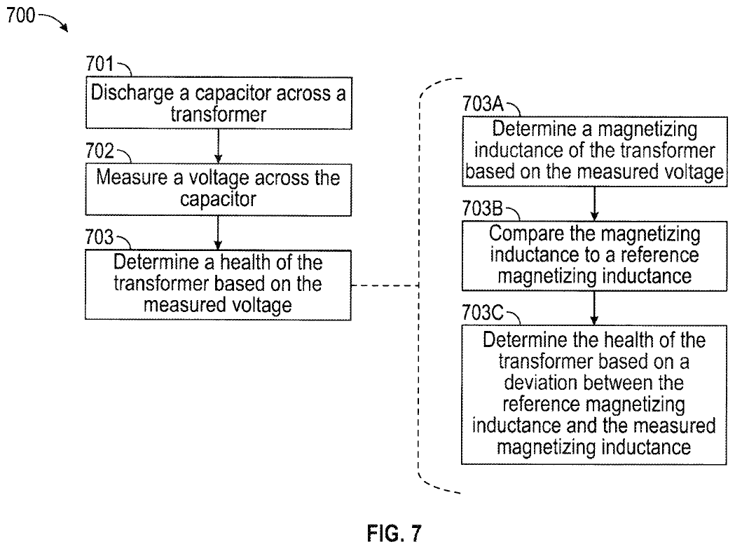

FIG. 7 shows a method 700 for determining the health of a transformer (e.g., transformer 218 or transformer 335, e.g., where the transformer is part of a DAB converter, e.g., DAB converter 114). At 701, control circuitry (e.g., as shown in FIG. 2) discharges a capacitor (e.g., any one or more of capacitors 354, 356, 358, 360, 362, and 364) across the transformer. For example, the control circuitry may cause the capacitor to discharge based on applying the switch signals Q₁ 502 and Q₃ 504, or Q₁ 602 and Q₃ 604. In some embodiments, control circuitry discharges the capacitor in accordance with the aforementioned first scheme, in which the control circuitry causes the DAB converter to operate in configuration 300 for a predetermined amount of time (e.g., T_{dis} 507), and then the control circuitry causes the DAB converter to operate in configuration 400. In other embodiments, control circuitry discharges the capacitor in accordance with the aforementioned second scheme, in which the control circuitry causes the DAB converter to operate in configuration 300 until a voltage across the capacitor (e.g., Vₒᵤₜ 606) reduces to zero (e.g., as shown by V_{drop} 608, with reference to the aforementioned note regarding a zero voltage).

At 702, the control circuitry measures a voltage (e.g., Vₒᵤₜ 506 or Vₒᵤₜ 606) across the capacitor. In some embodiments (e.g., the aforementioned first scheme), measuring the voltage includes measuring at least two voltages, where a first voltage is measured before discharging the capacitor (e.g., before state 1, as shown in FIG. 5) and a second voltage is measured after discharging the capacitor (e.g., during state 2, as shown in FIG. 5). In some embodiments, measuring the voltage includes determining a difference between the first and second voltages. In some embodiments, measuring the voltage includes measuring a voltage while the capacitor is discharging (e.g., during state 1, as shown in FIG. 5, or during the period of T_{dis} 607). For example, measuring the voltage while the capacitor is discharging may continue a continuous measuring (e.g., in the analog domain) or a discrete measurement (e.g., in the digital domain) with a suitably high sampling rate so as to represent a continuous measurement. In some embodiments, measuring the voltage while the capacitor is discharging includes determining an initial time (e.g., corresponding to the left-most dashed vertical line of FIG. 6) associated with when the voltage begins to decrease and a final time (e.g., corresponding to the right-most dashed vertical line of FIG. 6) associated with when the voltage drops to zero (with reference to the aforementioned note about zero voltage). In some embodiments, measuring the voltage while the capacitor is discharging includes determining a difference between the initial time and the final time (e.g., determining T_{dis} 607).

At 703, the control circuitry determines a health of the transformer based on the measured voltage. In some embodiments, the health may be determined based on comparing a measured voltage drop (e.g., V_{drop} 508) to a reference voltage drop (e.g., where the reference voltage drop was recorded on commissioning of the system, or was otherwise recorded at an earlier time). In some embodiments, the health may be determined based on determining whether a deviation between the measured voltage drop and the reference voltage drop is greater than a threshold deviation. In some embodiments, the health may be determined based on comparing a measured time to fully discharge (e.g., T_{dis} 607) to a reference time to fully discharge (e.g., where the reference time to fully discharge was recorded on commissioning of the system, or was otherwise recorded at an earlier time). In some embodiments, the health may be determined based on determining whether a deviation between the measured time to fully discharge and the reference time to fully discharge is greater than a threshold deviation. In some embodiments, the reference voltage drop and the reference time to fully discharge may be stored in memory 111 of the PEM 105.

In some embodiments, method 700 includes particular operations at 703 (e.g., as also performed by the control circuitry), as shown on the right side of FIG. 7. At 703A, the magnetizing inductance of the transformer is determined based on the measured voltage. The magnetized inductance may be calculated based on the measured voltage and further based on other properties of the transformer (e.g., the magnetizing resistance, the leakage inductance of one or more windings of the transformer, or any combination thereof), properties of other electronic devices connected to the transformer (e.g., the capacitance of the capacitor, the resistance of wiring and switches coupled between the capacitor and the inductor, other suitable electronic properties or any combination thereof), or any combination thereof. For example, the magnetized inductance calculation may be based on the measured voltage and the abovementioned data used to calculate the magnetizing inductance 337.

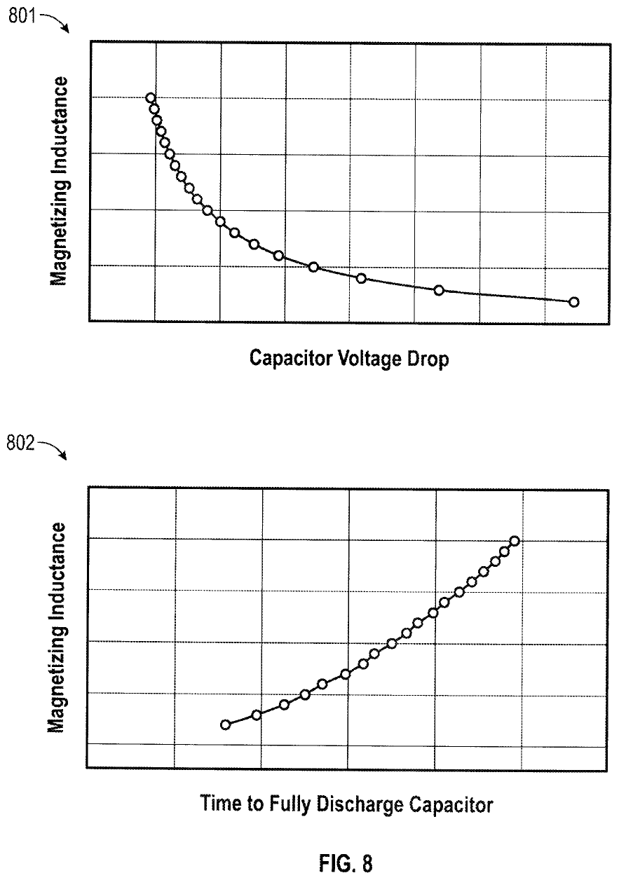

In some embodiments, method 700 may be repeated twice (e.g., using the first and second schemes for determining the magnetizing inductance), and the health of the transformer may be determined based on an average magnetizing inductance recorded across the two schemes. For example, V_{drop} 508 and T_{dis} 607 may be separately measured (e.g., in any particular order, with or without recharging the output capacitor between operation of the respective schemes), and two corresponding magnetizing inductance values (e.g., using the relationships as shown in FIG. 8) may be determined. Then, a determination of the health of the transformer may use the average magnetizing inductance value as the measured value (e.g., for comparison to a reference value).

In some embodiments, at 703B, the magnetizing inductance (e.g., as determined at 703A) is compared to a reference magnetizing inductance. The reference or nominal magnetizing inductance may be stored in memory 111 of the PEM 105. In some embodiments, the reference magnetizing inductance is based on a specification associated with a new transformer 218 or 335; in other embodiments, the reference magnetizing inductance is a value measured upon initial construction or commissioning of the DAB converter 114; in other embodiments, the reference magnetizing inductance is a value that was previously calculated (e.g., using the systems and methods disclosed herein). It is noted that the reference voltage drop and the reference time to fully discharge, as mentioned above, may be determined in conjunction with determining the reference magnetizing inductance.

In some embodiments, at 703C, the health of the transformer is determined based on a deviation between the reference magnetizing inductance and the measured magnetizing inductance. For example, the health of the transformer may be determined to be poor if the magnetizing inductance is less than 80% (or 70%, 90%, or any other suitable fraction) of the nominal magnetizing inductance. In some embodiments, at 703C, it is determined whether the magnetizing inductance deviates from the nominal value by a first threshold (e.g., which is associated with operating the DAB converter in a modified mode) or by a second threshold (e.g., which is associated with ceasing all operation of the DAB converter).

In some embodiments, method 700 also includes operating a DAB converter based on the health of the transformer (e.g., where the DAB converter includes the transformer). For example, the DAB converter may be operated according to the first or second threshold described above, or any other number of thresholds, where each threshold is associated with (i) a particular deviation between the measured magnetizing inductance and the nominal magnetizing inductance and (ii) a particular scheme for operating the DAB converter. In some embodiments, one or more schemes of operating the DAB converter includes one or more modes of operation, in which a respective mode limits an output power of the DAB converter to be a predetermined threshold or percentage of the maximum rated output power. In some embodiments, a scheme of operating the DAB converter includes limiting the output power to zero (e.g., not converting any power) based on the poor health of the transformer.

In some embodiments, method 700 also includes sending a notification in response to determining that the health of the transformer is poor, or sending a notification to otherwise report on the determined health of the transformer. For example, the notification may be sent to an owner or operator of the DAB converter 114, an electricity supplier providing power to DAB converter 114, one or more vehicle owners or operators who are configured to receive alerts pertaining to DAB converter 114 (e.g., because they use or are expected to use the DAB converter), a local authority or service provider, or any combination thereof.

FIG. 8 shows illustrative relationships between the magnetizing inductance and properties measured while discharging the capacitor. Relationship 801 shows the magnetizing inductance of the transformer (e.g., transformer 218 or 335) on the vertical axis as a function of the capacitor voltage drop (e.g., V_{drop} 508) on the horizontal axis. The magnetizing inductance nonlinearly decreases with increasing capacitor voltage drop. Therefore, a larger capacitive voltage drop (e.g., compared to a voltage drop recorded when commissioning the transformer or any other previously-measured voltage drop) may be indicative of worsening health of the transformer. Relationship 802 shows the magnetizing inductance of the transformer (e.g., transformer 218 or 335) on the vertical axis as a function of the time to fully discharge the capacitor (e.g., T_{dis} 607) on the horizontal axis. The magnetizing inductance nonlinearly decreases with decreasing time to fully discharge the capacitor. Therefore, a shorter time to fully discharge the capacitor (e.g., compared to a full discharging time recorded when commissioning the transformer or any other previously-measured full discharge time) may be indicative of worsening health of the transformer.

In some embodiments, the relationships 801 and 802 may be stored in memory 111 (e.g., in the settings 202, instructions 204, rules 206, or any combination thereof). For example, the memory 111 can store one or more curves for each relationship (even though only one illustrative curve is shown for each relationship in FIG. 8), where each one of the one or more curves corresponds to particular properties of the DAB converter (e.g., particular values for the abovementioned data used to calculate the magnetizing inductance 337). In some embodiments, the control circuitry may be configured to determine the relationships 801 and 802 based on settings 202, instructions 204, rules 206, or any combination thereof. For example, control circuitry may determine particular values for the abovementioned data used to calculate the magnetizing inductance 337 and then determine the relationships 801 and 802 based on these particular values.

The processes described above are intended to be illustrative and not limiting. One skilled in the art would appreciate that the steps of the processes described herein may be omitted, modified, combined and/or rearranged, and any additional steps may be performed without departing from the scope of the invention.

The foregoing is merely illustrative of the principles of this disclosure, and various modifications may be made by those skilled in the art without departing from the scope of this disclosure. The above-described embodiments are presented for purposes of illustration and not of limitation. The present disclosure also can take many forms other than those explicitly described herein. Accordingly, it is emphasized that this disclosure is not limited to the explicitly disclosed methods, systems, and apparatuses, but is intended to include variations thereto and modifications thereof, which are within the spirit of the following claims.

What is claimed is:

1. A system comprising:
a transformer;
a capacitor; and
control circuitry configured to:
discharge the capacitor across the transformer;
measure a voltage across the capacitor; and
determine a health of the transformer based on the measured voltage.

2. The system of claim 1, wherein the control circuitry is configured to:
measure the voltage across the capacitor by measuring a first voltage across the capacitor before the capacitor is discharged and measuring a second voltage across the capacitor after a predetermined amount of time; and
determine the health of the transformer based on a difference between the first voltage and the second voltage.

3. The system of claim 2, wherein the predetermined amount of time is based on a time constant of a current loop comprising the transformer and the capacitor.

4. The system of claim 1, wherein:
the control circuitry is configured to determine an amount of time that the capacitor takes to fully discharge; and
the control circuitry is configured to determine the health of the transformer based on the amount of time that the capacitor takes to fully discharge.

5. The system of claim 1, wherein the control circuitry is further configured to determine the health of the transformer based on the measured voltage by:
determining a magnetizing inductance of the transformer; and
determining whether the magnetizing inductance is less than a reference magnetizing inductance by more than a predetermined amount.

6. The system of claim 1, further comprising a plurality of switches, wherein the control circuitry is further configured to:
close a switch of the plurality of switches; and
after a predetermined amount of time has passed after closing the switch, open the switch and close a different switch of the plurality of switches, such that the capacitor stops discharging.

7. The system of claim 6, wherein the control circuitry is configured to close the switch by applying a pulse-width modulation (PWM) signal to the switch and wherein a duty cycle or a frequency of the PWM signal is based on a current rating of the switch.

8. The system of claim 1, wherein the control circuitry is further configured to, in response to determining that the transformer has poor health:
generate a notification indicating the poor health of the transformer; and
operate a dual active bridge converter comprising the transformer based on the poor health of the transformer.

9. A method comprising:
discharging a capacitor across a transformer;
measuring a voltage across the capacitor; and
determining a health of the transformer based on the measured voltage.

10. The method of claim 9, wherein:
measuring the voltage across the capacitor comprises measuring a first voltage across the capacitor before the capacitor is discharged and measuring a second voltage across the capacitor after a predetermined amount of time; and
determining the health of the transformer is based on a difference between the first voltage and the second voltage.

11. The method of claim 10, wherein the predetermined amount of time is based on a time constant of a current loop comprising the transformer and the capacitor.

12. The method of claim 9, further comprising:
determining an amount of time that the capacitor takes to fully discharge, wherein determining the health of the transformer based on the amount of time that the capacitor takes to fully discharge.

13. The method of claim 9, wherein determining the health of the transformer based on the measured voltage comprises:
determining a magnetizing inductance of the transformer; and
determining whether the magnetizing inductance is less than a reference magnetizing inductance by more than a predetermined amount.

14. The method of claim 9, further comprising:
closing a switch to discharge the capacitor across the transformer; and
after a predetermined amount of time has passed after closing the switch, opening the switch and closing a different switch such that the capacitor stops discharging.

15. The method of claim 14, wherein closing the switch comprises applying a pulse-width modulation (PWM) signal to the switch and wherein a duty cycle or a frequency of the PWM signal is based on a current rating of the switch.

16. The method of claim 9, further comprising, in response to determining that the transformer has poor health:
generating a notification indicating the poor health of the transformer; and
operating a dual active bridge converter comprising the transformer based on the poor health of the transformer.

17. A non-transitory computer-readable medium having non-transitory computer-readable instructions encoded thereon that, when executed by a processor, cause the processor to:
discharge a capacitor across a transformer;
measure a voltage across the capacitor; and
determine a health of the transformer based on the measured voltage.

18. The non-transitory computer-readable medium of claim 17, wherein the instructions, when executed by the processor, further cause the processor to:
measure a first voltage across the capacitor before the capacitor is discharged and measure a second voltage across the capacitor after a predetermined amount of time; and
determine the health of the transformer based on a difference between the first voltage and the second voltage.

19. The non-transitory computer-readable medium of claim 17, wherein the instructions, when executed by the processor, further cause the processor to:
determine an amount of time that the capacitor takes to fully discharge; and
determine the health of the transformer based on the amount of time that the capacitor takes to fully discharge.

20. The non-transitory computer-readable medium of claim 17, wherein the instructions, when executed by the processor, further cause the processor to:
determine a magnetizing inductance of the transformer based on the measured voltage; and
determine the health of the transformer based on determining whether the magnetizing inductance is less than a reference inductance by more than a predetermined amount.
